(19) United States
(12) Patent Application Publication
(10) Pub. No.: US 2022/0291586 A1
(43) Pub. Date: Sep. 15, 2022

(54) UNDERLAYER COMPOSITION AND METHOD OF MANUFACTURING A SEMICONDUCTOR DEVICE

(71) Applicant: TAIWAN SEMICONDUCTOR MANUFACTURING COMPANY, LTD., Hsinchu (TW)

(72) Inventors: Ming-Hui WENG, New Taipei City (TW); Chen-Yu LIU, Kaohsiung City (TW); Ching-Yu CHANG, Yuansun Village (TW)

(21) Appl. No.: 17/486,223

(22) Filed: Sep. 27, 2021

Related U.S. Application Data
(60) Provisional application No. 63/159,334, filed on Mar. 10, 2021.

(51) Int. Cl. G03F 7/039; G03F 7/004; G03F 7/38; G03F 7/40; G03F 7/20; G03F 7/075; G03F 7/32

(52) U.S. Cl. CPC G03F 7/0392; G03F 7/0045; G03F 7/38; G03F 7/40; G03F 7/2004; G03F 7/0755; G03F 7/325

(57) ABSTRACT

A method for manufacturing a semiconductor device includes forming a resist underlayer over a substrate. The resist underlayer includes an underlayer composition, including: a polymer with pendant photoacid generator (PAG) groups, pendant thermal acid generator (TAG) groups, a combination of pendant PAG and pendant TAG groups, pendant photobase generator (PBG) groups, pendant thermal base generator (TBG) groups, or a combination of pendant PBG and pendant TBG groups. A photoresist layer including a photoresist composition is formed over the resist underlayer. The photoresist layer is selectively exposed to actinic radiation. The selectively exposed photoresist layer is developed to form a pattern in the photoresist layer.

### CROSS-REFERENCE TO RELATED APPLICATION

This application claims priority to U.S. Provisional Patent Application No. 63/159,334, filed Mar. 10, 2021, the entire disclosure of which is incorporated herein by reference.

### BACKGROUND

As consumer devices have gotten smaller and smaller in response to consumer demand, the individual components of these devices have necessarily decreased in size as well. Semiconductor devices, which make up a major component of devices such as mobile phones, computer tablets, and the like, have been pressured to become smaller and smaller, with a corresponding pressure on the individual devices (e.g., transistors, resistors, capacitors, etc.) within the semiconductor devices to also be reduced in size.

One enabling technology that is used in the manufacturing processes of semiconductor devices is the use of photolithographic materials. Such materials are applied to a surface of a layer to be patterned and then exposed to an energy that has itself been patterned. Such an exposure modifies the chemical and physical properties of the exposed regions of the photosensitive material. This modification, along with the lack of modification in regions of the photosensitive material that were not exposed, can be exploited to remove one region without removing the other.

However, as the size of individual devices has decreased, process windows for photolithographic processing has become tighter and tighter. As such, advances in the field of photolithographic processing are necessary to maintain the ability to scale down the devices, and further improvements are needed in order to meet the desired design criteria such that the march towards smaller and smaller components may be maintained.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a process flow of manufacturing a semiconductor device according to embodiments of the disclosure.

FIG. 2 shows a process stage of a sequential operation according to an embodiment of the disclosure.

FIG. 3A and 3B show a process stage of a sequential operation according to embodiments of the disclosure.

FIG. 4 shows a process stage of a sequential operation according to an embodiment of the disclosure.

FIGS. 5A and 5B show a process stage of a sequential operation according to embodiments of the disclosure.

FIGS. 6A and 6B show a process stage of a sequential operation according to embodiments of the disclosure.

FIGS. 7A, 7B, and 7C illustrate polymers containing photoacid generators and thermal acid generators according to embodiments of the disclosure.

FIGS. 8A, 8B, and 8C illustrate polymers containing photobase generators and thermal base generators according to embodiments of the disclosure.

FIG. 9 illustrates photoacid generators according to embodiments of the disclosure.

FIGS. 10A and 10B illustrate reactions of acid generator groups according to embodiments of the disclosure. FIG. 10C illustrates acid generator groups with sensitizer cores according to embodiments of the disclosure. FIG. 10D illustrates examples of sensitizer cores according to embodiments of the disclosure.

FIG. 11A illustrates a quenching mechanism according to embodiments of the disclosure. FIG. 11B illustrates photobase generator reaction according to embodiments of the disclosure.

FIGS. 12A and 12B illustrate a photoresist pattern over an underlayer according to embodiments of the disclosure.

FIG. 13 shows a process stage of a sequential operation according to an embodiment of the disclosure.

FIGS. 14A and 14B show a process stage of a sequential operation according to embodiments of the disclosure.

FIG. 15 shows a process stage of a sequential operation according to an embodiment of the disclosure.

FIGS. 16A and 16B show a process stage of a sequential operation according to embodiments of the disclosure.

FIGS. 17A and 17B show a process stage of a sequential operation according to embodiments of the disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Extreme ultraviolet (EUV) lithography to achieve sub-20 nm half-pitch resolution is under development for mass production for next generation sub 5 nm node. EUV lithography requires a high performance photoresist with high sensitivity for cost reduction of the high-power exposure source, and to provide good resolution of the image.

However, in a positive tone developing process, the concentration of acid, which is generated by a photoacid generator in a photoresist layer may be insufficient at the bottom of the photoresist layer. The lower amount of acid may cause low photoresist polymer solubility in the developer, such as a tetramethyl ammonium hydroxide (TMAH) solution, thereby producing scum. In a negative tone developing process, the acid generated by the photoacid generator at the exposure area may diffuse to the non-exposure area to cause low polymer solubility in the developer, such as an organic solvent, thereby producing scum. A dry descum process may be performed to remove the bottom scum. However, the non-selective descum process may also consume a portion of the desired photoresist pattern, and cause bridge defects after pattern transferring. Embodiments of the disclosure prevent or inhibit the formation of bottom scum.

Embodiments of this disclosure provide improved integrity of the photoresist pattern and decreased line width roughness, line edge roughness, and scum reduction. Embodiments of the disclosure allow reduced exposure doses.

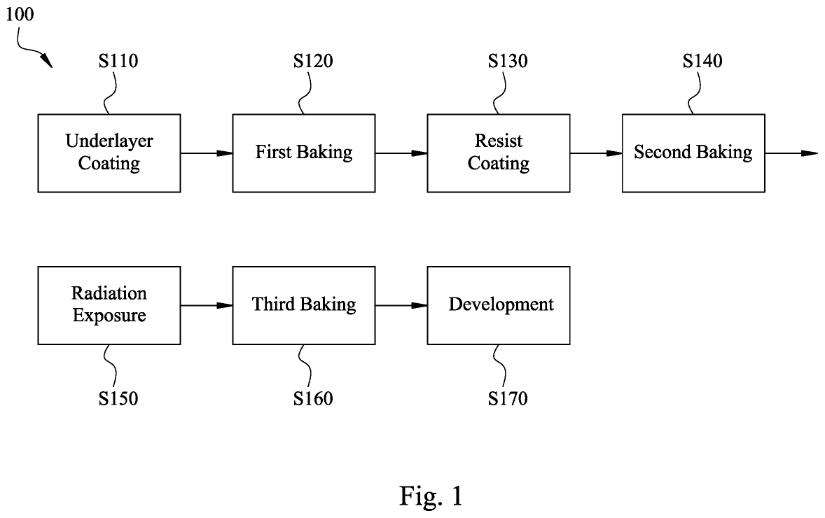

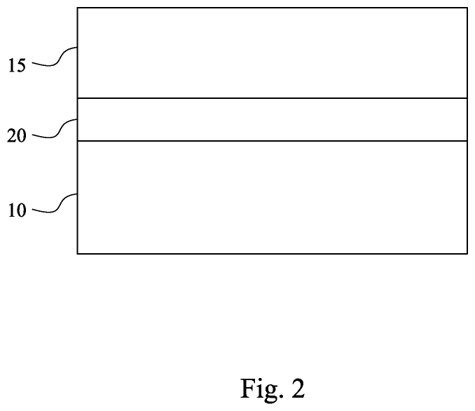

FIG. 1 illustrates a process flow 100 of manufacturing a semiconductor device according to embodiments of the disclosure. A resist underlayer (or bottom layer) composition is coated on a surface of a layer to be patterned (target layer) or a substrate 10 in operation S110, in some embodiments, to form a resist underlayer (or bottom layer) 20, as shown in FIG. 2. In some embodiments, the resist underlayer 20 has a thickness ranging from about 2 nm to about 300 nm. In some embodiments, the resist underlayer has a thickness ranging from about 20 nm to about 100 nm. Then the resist underlayer 20 undergoes a first baking operation S120 to evaporate solvents in the underlayer composition in some embodiments. The underlayer 20 is baked at a temperature and time sufficient to cure and dry the underlayer 20. In some embodiments, the underlayer is heated at a temperature in a range of about 80° C. to about 300° C. for about 10 seconds to about 10 minutes. In some embodiments, the underlayer is heated at a temperature ranging from about 150° C. to about 250° C.

A resist layer composition is subsequently coated on a surface of the resist underlayer 20 in operation S130, in some embodiments, to form a resist layer 15, as shown in FIG. 2. In some embodiments, the resist layer 15 is a photoresist layer. Then the resist layer 15 undergoes a second baking operation S140 (or pre-exposure baking operation) to evaporate solvents in the resist composition in some embodiments. The resist layer 15 is baked at a temperature and time sufficient to cure and dry the photoresist layer 15. In some embodiments, the resist layer is heated at a temperature of about 40° C. to 150° C. for about 10 seconds to about 10 minutes. In some embodiments, the resist layer composition is coated on the resist underlayer 20 prior to baking the resist underlayer 20, and the resist layer 15 and resist underlayer 20 are baked together in a single baking operation to drive off solvents of both layers.

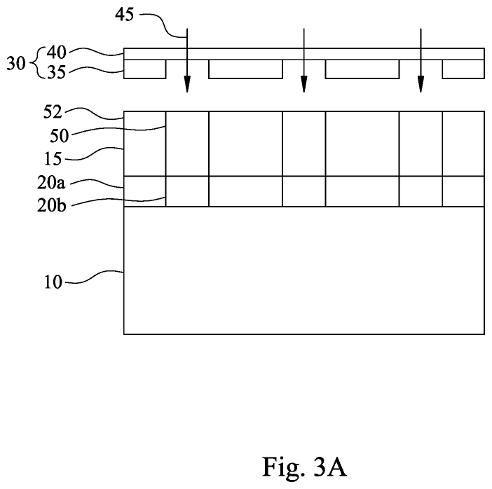

After the second (or pre-exposure) baking operation S140 of the photoresist layer 15, the photoresist layer 15 is selectively exposed to actinic radiation 45/97 (see FIGS. 3A and 3B) in operation S150. In some embodiments, the photoresist layer 15 is selectively exposed to ultraviolet radiation. In some embodiments, the radiation is electromagnetic radiation, such as g-line (wavelength of about 436 nm), i-line (wavelength of about 365 nm), ultraviolet radiation, deep ultraviolet radiation, extreme ultraviolet, electron beams, or the like. In some embodiments, the radiation source is selected from the group consisting of a mercury vapor lamp, xenon lamp, carbon arc lamp, a KrF excimer laser light (wavelength of 248 nm), an ArF excimer laser light (wavelength of 193 nm), an F2 excimer laser light (wavelength of 157 nm), or a CO₂ laser-excited Sn plasma (extreme ultraviolet, wavelength of 13.5 nm).

As shown in FIG. 3A, the exposure radiation 45 passes through a photomask 30 before irradiating the photoresist layer 15 in some embodiments. In some embodiments, the photomask has a pattern to be replicated in the photoresist layer 15. The pattern is formed by an opaque pattern 35 on the photomask substrate 40, in some embodiments. The opaque pattern 35 may be formed by a material opaque to ultraviolet radiation, such as chromium, while the photomask substrate 40 is formed of a material that is transparent to ultraviolet radiation, such as fused quartz.

In some embodiments, the selective exposure of the photoresist layer 15 to form exposed regions 50 and unexposed regions 52 is performed using extreme ultraviolet lithography. In an extreme ultraviolet lithography operation a reflective photomask 65 is used to form the patterned exposure light in some embodiments, as shown in FIG. 3B. The reflective photomask 65 includes a low thermal expansion glass substrate 70, on which a reflective multilayer 75 of Si and Mo is formed. A capping layer 80 and absorber layer 85 are formed on the reflective multilayer 75. A rear conductive layer 90 is formed on the back side of the low thermal expansion glass substrate 70. In extreme ultraviolet lithography, extreme ultraviolet radiation 95 is directed towards the reflective photomask 65 at an incident angle of about 6°. A portion 97 of the extreme ultraviolet radiation is reflected by the Si/Mo multilayer 75 towards the photoresist coated substrate 10, while the portion of the extreme ultraviolet radiation incident upon the absorber layer 85 is absorbed by the photomask. In some embodiments, additional optics, including mirrors, are between the reflective photomask 65 and the photoresist coated substrate.

The region of the photoresist layer exposed to radiation 50 undergoes a chemical reaction thereby changing its solubility in a subsequently applied developer relative to the region of the photoresist layer not exposed to radiation 52. In some embodiments, the portion of the photoresist layer exposed to radiation 50 undergoes a crosslinking reaction. In addition to causing the chemical reaction in the photoresist layer 15, a portion of the radiation 45/97 also passes through the photoresist layer 15 and causes a reaction in the resist underlayer 20. The reaction in the resist underlayer 20 results in a small molecule being generated, which subsequently diffuses into the photoresist layer 15. FIGS. 3A and 3B show exposed portions 20b and non-exposed portions 20a of the resist underlayer 20.

Next, the photoresist layer 15 and the resist underlayer 20 undergoes a third baking (or post-exposure bake (PEB)) in operation S160. In some embodiments, the photoresist layer 15 is heated at a temperature of about 50° C. to 200° C. for about 20 seconds to about 120 seconds. The post-exposure baking may be used to assist in the generating, dispersing, and reacting of the acid generated in the portions of the underlayer exposed to actinic radiation 45/97 from the impingement of the radiation 45/97 upon the photoresist layer 15 during the exposure, and to assist in the diffusion of the acid or base generated in the exposed portion of the photoresist layer 15 from the exposed portion 20b of the resist underlayer into the photoresist layer 15. Such assistance helps to create or enhance chemical reactions, which generate chemical differences between the exposed region 50 and the unexposed region 52 within the photoresist layer.

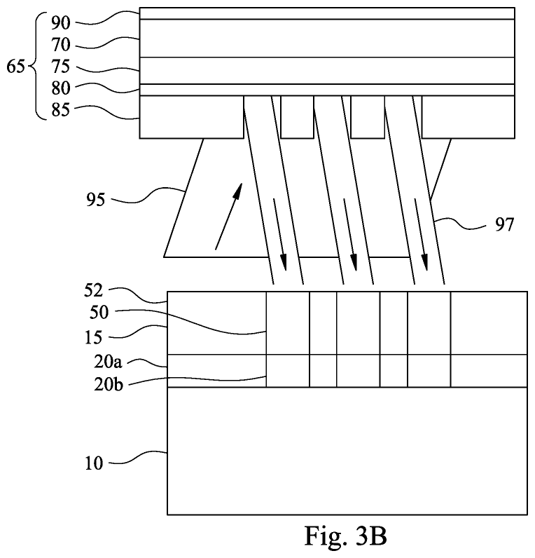

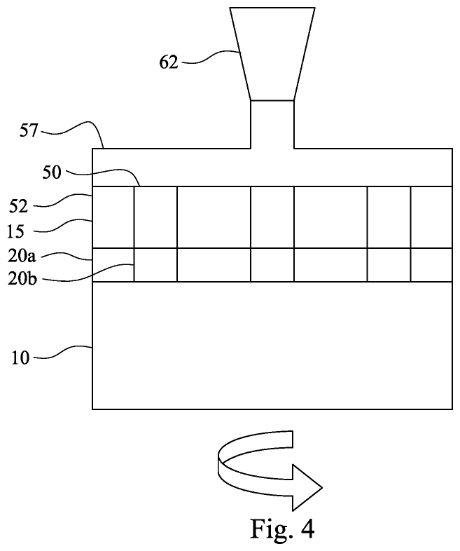

The selectively exposed photoresist layer is subsequently developed by applying a developer to the selectively exposed photoresist layer in operation S170. As shown in FIG. 4, a developer 57 is supplied from a dispenser 62 to the photoresist layer 15. In some embodiments, the exposed region 50 of the photoresist is removed by the development operation S170, as shown in FIG. 5A to form a pattern of openings 55a in the photoresist layer exposing portions of the underlayer 20b that were exposed to the actinic radiation. In other embodiments, the unexposed region 52 of the photoresist layer is removed by the developer 57 forming a pattern of openings 55b in the photoresist layer 15 exposing portions of the underlayer 20a, as shown in FIG. 5B. In some embodiments, portions of the underlayer 20 exposed to the developer 57 are removed by the developer 57 during the development operation S170.

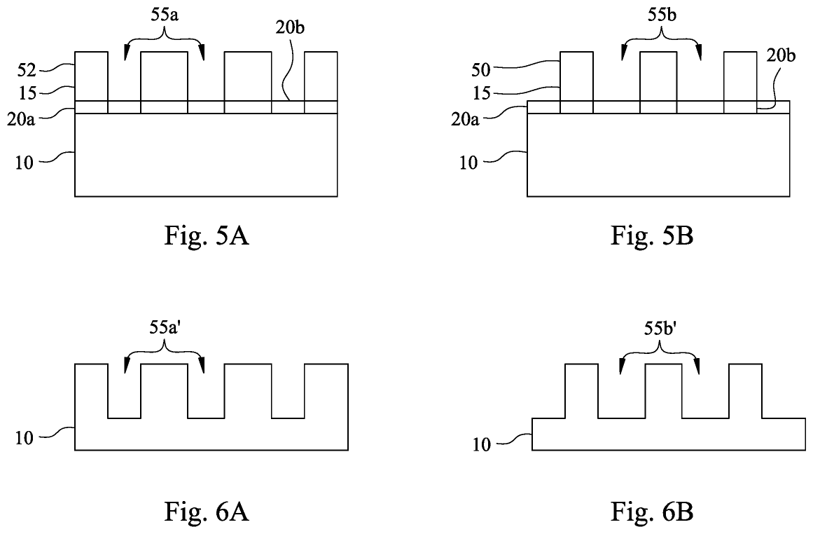

In some embodiments, the pattern of openings 55a, 55b in the photoresist layer 15 is extended through the underlayer 20 into the substrate 10 to create a pattern of openings 55a′, 55b′ in the substrate 10, thereby transferring the pattern in the photoresist layer 15 into the substrate 10, as shown in FIGS. 6A and 6B. The pattern is extended into the substrate by etching, using one or more suitable etchants. In some embodiments, the etching operation removes the portions of the underlayer 20a, 20b between the photoresist pattern features 55a, 55b. The photoresist layer pattern 50, 52 is at least partially removed during the etching operation in some embodiments. In other embodiments, the photoresist layer pattern 50, 52 and the remaining portion of the underlayer 20a, 20b under the photoresist layer pattern are removed after etching the substrate 10 by using a suitable photoresist stripper solvent or by a photoresist ashing operation.

In some embodiments, the substrate 10 includes a single crystalline semiconductor layer on at least it surface portion. The substrate 10 may include a single crystalline semiconductor material such as, but not limited to Si, Ge, SiGe, GaAs, InSb, GaP, GaSb, InAlAs, InGaAs, GaSbP, GaAsSb and InP. In some embodiments, the substrate 10 is a silicon layer of an SOI (silicon-on insulator) substrate. In certain embodiments, the substrate 10 is made of crystalline Si.

The substrate 10 may include in its surface region, one or more buffer layers (not shown). The buffer layers can serve to gradually change the lattice constant from that of the substrate to that of subsequently formed source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In an embodiment, the silicon germanium (SiGe) buffer layer is epitaxially grown on the silicon substrate 10. The germanium concentration of the SiGe buffer layers may increase from 30 atomic % for the bottom-most buffer layer to 70 atomic % for the top-most buffer layer.

In some embodiments, the substrate 10 includes one or more layers of at least one metal, metal alloy, and metal nitride/sulfide/oxide/silicide having the formula MXa, where M is a metal and X is N, S, Se, O, Si, and a is from about 0.4 to about 2.5. In some embodiments, the substrate 10 includes titanium, aluminum, cobalt, ruthenium, titanium nitride, tungsten nitride, tantalum nitride, and combinations thereof.

In some embodiments, the substrate 10 includes a dielectric having at least a silicon or metal oxide or nitride of the formula MXb, where M is a metal or Si, X is N or O, and b ranges from about 0.4 to about 2.5. In some embodiments, the substrate 10 includes silicon dioxide, silicon nitride, aluminum oxide, hafnium oxide, lanthanum oxide, and combinations thereof.

In some embodiments, the resist underlayer 20 improves the adhesion of the resist layer 20 to the substrate. In some embodiments, the resist underlayer 20 functions as a bottom anti-reflective coating (BARC). The BARC absorbs actinic radiation that passes through the photoresist layer, thereby preventing the actinic radiation from reflecting off the substrate or a target layer and exposing unintended portions of the photoresist layer. Thus, the BARC improves line width roughness and line edge roughness of the photoresist pattern.

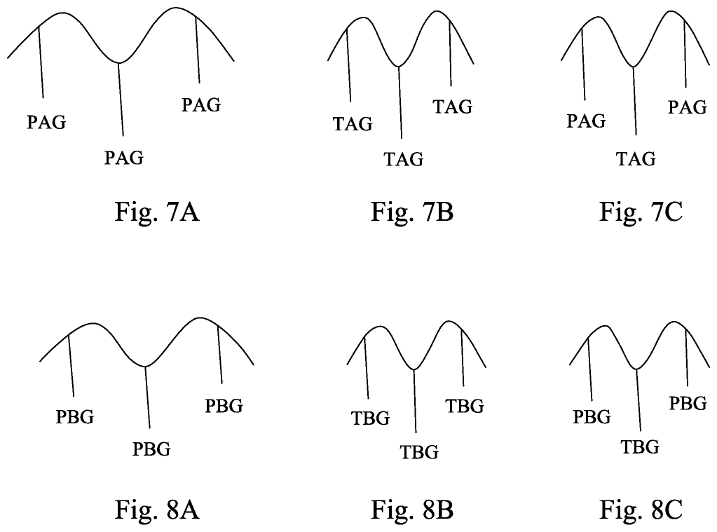

The resist underlayer 20 is made of polymer compositions in some embodiments, wherein the polymer has a main polymer chain (or backbone) with pendant photoacid generator (PAG) groups, thermal acid generator (TAG) groups, and combinations of PAG and TAG groups. Examples of polymers with pendant PAG and TAG groups are shown in FIGS. 7A, 7B, and 7C. When both PAG and TAG pendant groups are present on the same polymer, a ratio of the number of PAG groups/TAG groups on the polymer ranges from about 99/1 to about 1/99 in some embodiments. In some embodiments, the ratio of the number of PAG groups/TAG groups ranges from about 3/1 to about 1/3. In other embodiments, the ratio of the number of PAG groups/TAG groups ranges from about 3/2 to about 2/3.

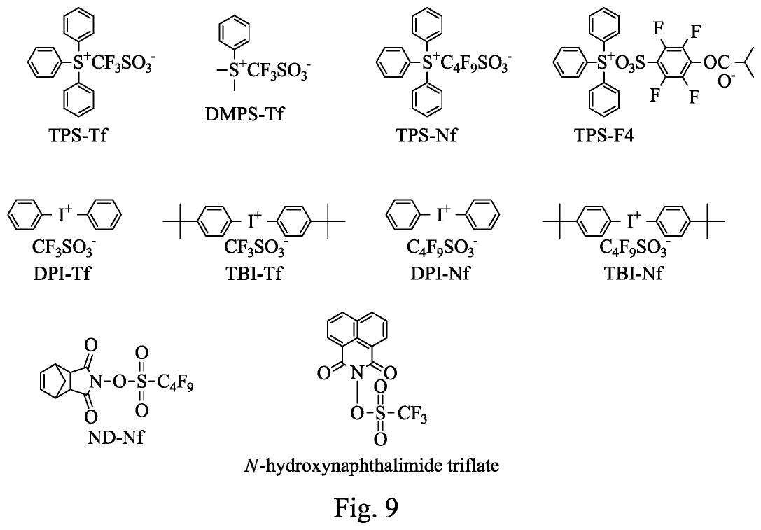

In some embodiments, the resist underlayer 20 is made of polymer compositions, wherein the polymer has a main polymer chain (or backbone) with pendant photobase generator (PBG) groups, thermal base generator (TBG) groups, and combinations of PBG and TBG groups. Examples of polymers with pendant PBG and TBG groups are shown in FIGS. 8A, 8B, and 8C. When both PBG and TBG pendant groups are present on the same polymer, a ratio of the number of PBG groups/TBG groups on the polymer ranges from about 99/1 to about 1/99 in some embodiments. In some embodiments, the ratio of the number of PBG groups/TBG groups ranges from about 3/1 to about 1/3. In other embodiments, the ratio of the number of PBG groups/TBG groups ranges from about 3/2 to about 2/3.

In some embodiments, the polymer main chain or backbone is an organic polymer or an inorganic polymer. In some embodiments, the polymer main chain is formed from one or more monomers selected from the group consisting of acrylates, acrylic acids, siloxanes, hydroxystyrenes, methacrylates, vinyl esters, maleic esters, methacrylonitriles, and methacrylamides.

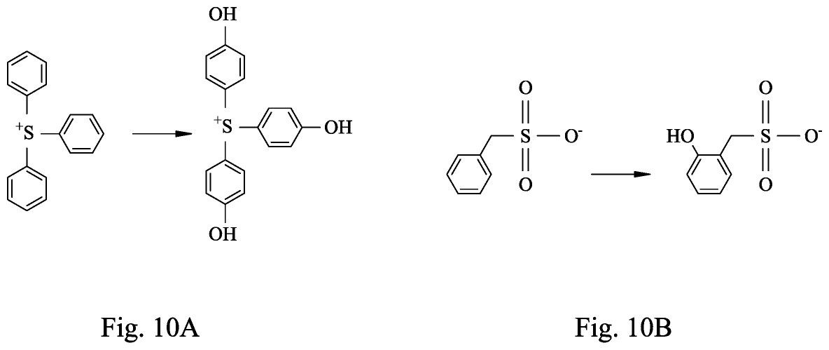

The pendant PAG groups bound to the polymer in the underlayer composition compounds according to some embodiments of the disclosure are illustrated in FIG. 9. The pendant PAG groups are one or more groups selected from the group consisting of a C3-C50 alkyl group containing fluorine atoms with at least one light-sensitive functional group. The PAG groups include N-hydroxynaphthalimide triflate, sulfonium salts, triphenylsulfonium triflate, triphenylsulfonium nonaflate, dimethylsulfonium triflate, iodonium salts, diphenyliodonium nonaflate, norbornene dicarboximidyl nonaflate, epoxy groups, azo groups, alkyl halide groups, imine groups, alkene groups, alkyne groups, peroxide groups, ketone groups, aldehyde groups, allene groups, aromatic groups, or heterocyclic groups. In some embodiments, the aromatic groups are phenyl groups, naphthalenyl groups, phenanthrenyl groups, anthracenyl groups, phenalenyl groups, or other aromatic groups containing one or more three to ten-membered rings.

In some embodiments, the thermal acid generator (TAG) group is one or more selected from the group consisting of

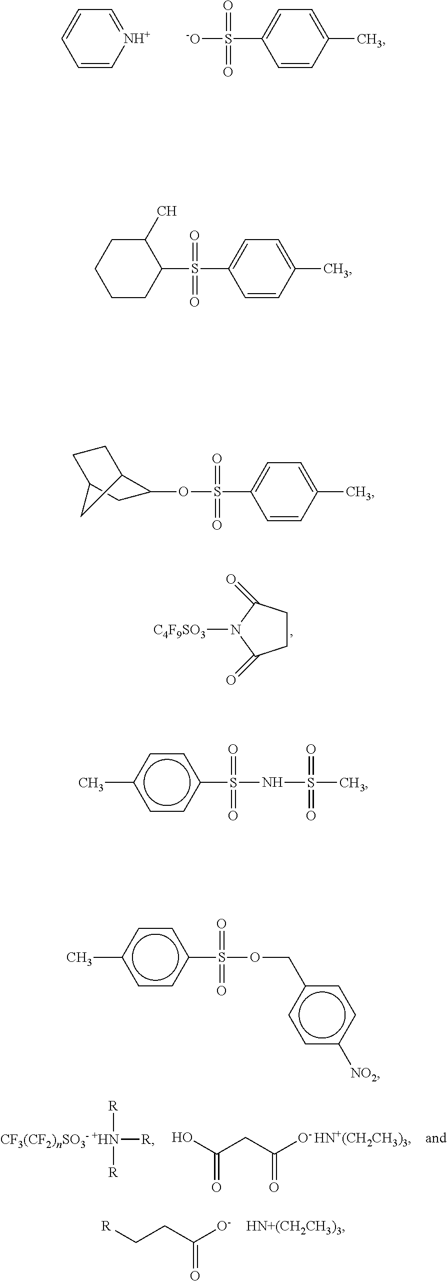

where 0≤n≤10, and R is hydrogen or a substituted or unsubstituted C1-C10 alkyl group. In some embodiments, the thermal acid generator group is at least one selected from NH₄⁺C₄F₉SO₃⁻ and NH₄⁺CF₃SO₃⁻.

In some embodiments, the photobase generator (PBG) group is selected from the group consisting of 1,2-dicyclohexyl-4,4,5,5-tetramethylbiguanidium n-butyltriphenylborate, 2-nitrophenyl methyl 4-methacryloyloxy piperidine-1-carboxylate, quaternary ammonium dithiocarbamates, α aminoketones, oxime-urethanes, dibenzophenoneoxime hexamethylene diurethans, ammonium tetraorganylborate salts, and N-(2-nitrobenzyloxycarbonyl)cyclic amines, and combinations thereof.

In some embodiments, the thermal base generator (TBG) group is one or more selected from the group consisting of

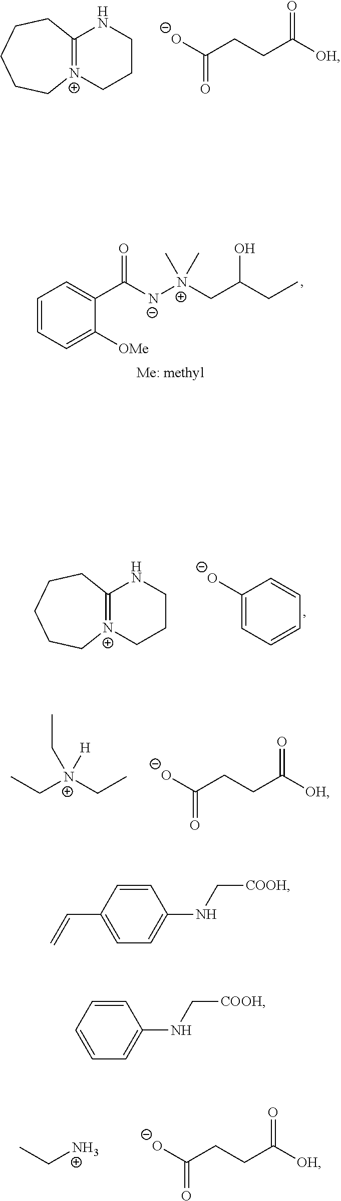

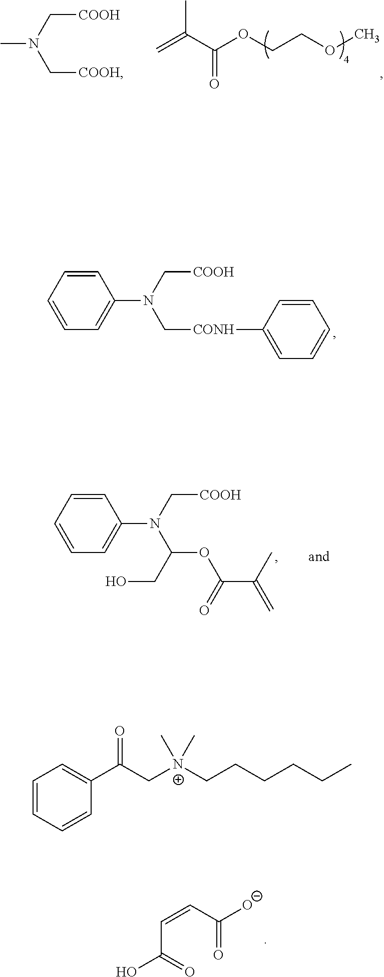

In some embodiments, the PAG group, TAG group, PBG group, or TBG group includes an element with a high EUV absorption, such as an EUV absorption greater than about 5×10⁵ cm²/gm. In some embodiments, the PAG group, TAG group, PBG group, or TBG group includes an element selected from the group consisting of F, Cl, Br, I, and combinations thereof.

In some embodiments, the PAG group, TAG group, PBG group, or TBG group includes a sensitizer core, wherein the sensitizer core includes n aromatic rings, where n≤5, and m proton source functional groups, where m≤2n+3. In some embodiments, the proton source functional groups include —OH or —SH. In some embodiments, the sensitizer core is a phenyl group, a naphthalenyl, a phenanthrenthyl group, or an anthracenyl group. In some embodiments, the sensitizer core is one or more selected from the group consisting of 1,3-naphthalenediol, 1-phenanthrenol, and 1,2,3-trihydroxybenzene.

In some embodiments, a concentration of the PAG group, TAG group, PBG group, or TBG group in the underlayer is less than about 50 wt. % based on a total weight of the underlayer composition. In some embodiments, a concentration of the PAG group, TAG group, PBG group or TBG group in the polymer composition is less than 50 wt. % based on a total weight of the polymer. In some embodiments, a concentration of the PAG group, TAG group, PBG group, or TBG group in the underlayer ranges from about 1 wt. % to about 50 wt. % based on a total weight of the underlayer composition. In other embodiments, a concentration of the PAG group, TAG group, PBG group, or TBG group in the underlayer ranges from about 5 wt. % to about 40 wt. % based on a total on a total weight of the underlayer composition. In some embodiments, a higher concentration of the PAG group, TAG group, PBG group, or TBG group is greater than about 30 wt. % based on a total weight of the polymer composition. In some embodiments, a lower concentration of the PAG group, TAG group, PBG group, or TBG group is less than about 30 wt. % based on a total weight of the polymer composition. At concentrations below the disclosed ranges there may not be a sufficient amount of the PAG, TAG, PBG, or TBG to provide the desired effect. At concentrations of the PAG, TAG, PBG, or TBG greater than the disclosed ranges substantial improvement in the photoresist pattern profile may not be obtained.

In some embodiments, the first baking operation S120 activates the TAG or TBG group and generates an acid or base, respectively. In other embodiments, the TAG or TBG group is activated during the second baking operation S140 or the third baking operation S160.

In some embodiments, the underlayer composition includes a quencher, which inhibits diffusion of the generated acids or bases. The quencher improves the resist pattern configuration as well as the stability of the photoresist over time. In an embodiment, the quencher is an amine, such as a second lower aliphatic amine, a tertiary lower aliphatic amine, or the like. Specific examples of amines include trimethylamine, diethylamine, triethylamine, di-n-propylamine, tri-n-propylamine, tripentylamine, diethanolamine, and triethanolamine, alkanolamine, combinations thereof, or the like.

In some embodiments, an organic acid is used as the quencher. Specific embodiments of organic acids include malonic acid, citric acid, malic acid, succinic acid, benzoic acid, salicylic acid; phosphorous oxo acid and its derivatives, such as phosphoric acid and derivatives thereof such as its esters, phosphoric acid di-n-butyl ester and phosphoric acid diphenyl ester; phosphonic acid and derivatives thereof such as its ester, such as phosphonic acid dimethyl ester, phosphonic acid di-n-butyl ester, phenylphosphonic acid, phosphonic acid diphenyl ester, and phosphonic acid dibenzyl ester; and phosphinic acid and derivatives thereof such as its esters, including phenylphosphinic acid.

In some embodiments, an additive, such as a surfactant, is added to the resist underlayer polymer composition. In some embodiments, the surfactants include nonionic surfactants, polymers having fluorinated aliphatic groups, surfactants that contain at least one fluorine atom and/or at least one silicon atom, polyoxyethylene alkyl ethers, polyoxyethylene alkyl aryl ethers, polyoxyethylene-polyoxypropylene block copolymers, sorbitan fatty acid esters, and polyoxyethylene sorbitan fatty acid esters.

Specific examples of materials used as surfactants in some embodiments include polyoxyethylene lauryl ether, polyoxyethylene stearyl ether, polyoxyethylene cetyl ether, polyoxyethylene oleyl ether, polyoxyethylene octyl phenol ether, polyoxyethylene nonyl phenol ether, sorbitan monolaurate, sorbitan monopalmitate, sorbitan monostearate, sorbitan monooleate, sorbitan trioleate, sorbitan tristearate, polyoxyethylene sorbitan monolaurate, polyoxyethylene sorbitan monopalmitate, polyoxyethylene sorbitan monostearate, polyoxyethylene sorbitan trioleate, polyoxyethylene sorbitan tristearate, polyethylene glycol distearate, polyethylene glycol dilaurate, polyethylene glycol dilaurate, polyethylene glycol, polypropylene glycol, polyoxyethylenestearyl ether, polyoxyethylene cetyl ether, fluorine containing cationic surfactants, fluorine containing nonionic surfactants, fluorine containing anionic surfactants, cationic surfactants and anionic surfactants, polyethylene glycol, polypropylene glycol, polyoxyethylene cetyl ether, combinations thereof, or the like.

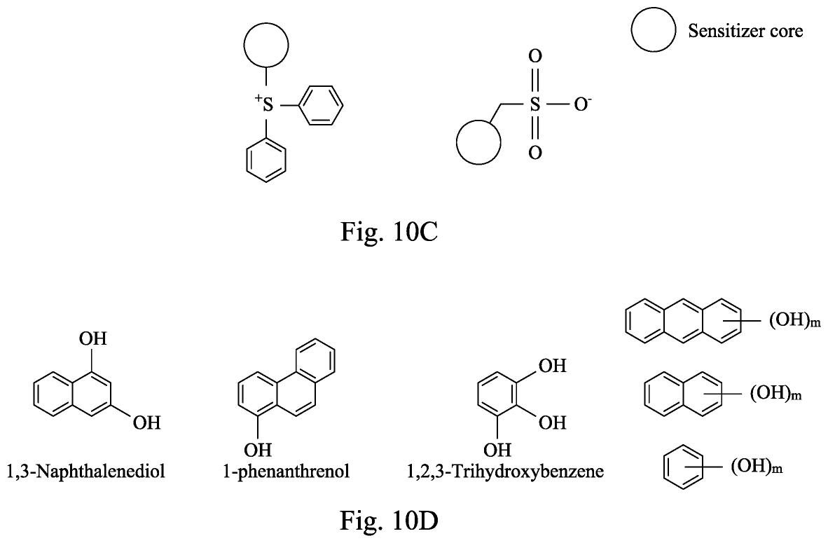

FIGS. 10A and 10B illustrate reactions that certain pendant PAG groups in the underlayer polymer composition undergo upon exposure to actinic radiation according to some embodiments.

FIG. 10C illustrates PAG groups with sensitizer cores according to some embodiments. FIG. 10D illustrates some embodiments of specific sensitizer cores, where m≤2n+3, and n is the number of aromatic rings in the sensitizer core.

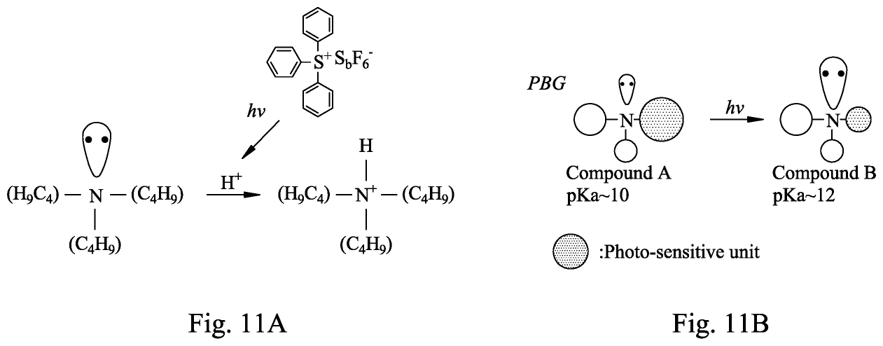

FIG. 11A illustrates a quenching reaction according to some embodiments. The quencher neutralizes excess acid generated by the actinic radiation exposure operation S150 and subsequent post exposure baking operation S160.

FIG. 11B illustrates the effect of exposing a PBG group to actinic radiation (hv). As shown, in some embodiments, the exposure to actinic radiation increases the pKa of the PBG group.

In some embodiments, the resist underlayer 20 is formed by preparing an underlayer coating composition of any of the polymer composition components disclosed herein in a solvent. The solvent can be any suitable solvent for dissolving the polymer and the selected components of the compositions. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK). The underlayer coating composition is applied over a substrate 10 or target layer, such as by spin coating. Then the underlayer composition is baked to dry the underlayer, as explained herein in reference to FIG. 1.

In some embodiments, the thickness of the resist underlayer 20 ranges from about 2 nm to about 300 nm, and in other embodiments, the resist underlayer thickness ranges from about 20 nm to about 100 nm. In some embodiments, the thickness of the resist underlayer 20 ranges from about 40 nm to about 80 nm. Resist underlayer thicknesses less than the disclosed ranges may be insufficient to provide adequate scum reduction, photoresist adhesion, LWR improvement, and anti-reflective properties. Resist underlayer thicknesses greater than the disclosed ranges may be unnecessarily thick and may not provide further improvement in resist layer adhesion, LWR improvement, and scum reduction.

In some embodiments, the photoresist layer 15 is a photosensitive layer that is patterned by exposure to actinic radiation. Typically, the chemical properties of the photoresist regions struck by incident radiation change in a manner that depends on the type of photoresist used. Photoresist layers 15 are either positive tone resists or negative tone resists. A positive tone resist refers to a photoresist material that when exposed to radiation, such as UV light, becomes soluble in a developer, while the region of the photoresist that is non-exposed (or exposed less) is insoluble in the developer. A negative tone resist, on the other hand, refers to a photoresist material that when exposed to radiation becomes insoluble in the developer, while the region of the photoresist that is non-exposed (or exposed less) is soluble in the developer. The region of a negative resist that becomes insoluble upon exposure to radiation may become insoluble due to a cross-linking reaction caused by the exposure to radiation.

Whether a resist is a positive tone or negative tone may depend on the type of developer used to develop the resist. For example, some positive tone photoresists provide a positive pattern, (i.e.—the exposed regions are removed by the developer), when the developer is an aqueous-based developer, such as a tetramethylammonium hydroxide (TMAH) solution. On the other hand, the same photoresist provides a negative pattern (i.e.—the unexposed regions are removed by the developer) when the developer is an organic solvent. Further, in some negative tone photoresists developed with the TMAH solution, the unexposed regions of the photoresist are removed by the TMAH, and the exposed regions of the photoresist, that undergo cross-linking upon exposure to actinic radiation, remain on the substrate after development.

In some embodiments, resist compositions according to embodiments of the disclosure, such as a photoresist, include a polymer or a polymerizable monomer or oligomer along with one or more photoactive compounds (PACs). In some embodiments, the concentration of the polymer, monomer, or oligomer ranges from about 1 wt. % to about 75 wt. % based on the total weight of the resist composition. In other embodiments, the concentration of the polymer, monomer, or oligomer ranges from about 5 wt. % to about 50 wt. %. At concentrations of the polymer, monomer, or oligomer below the disclosed ranges the polymer, monomer, or oligomer has negligible effect on the resist performance. At concentrations above the disclosed ranges, there is no substantial improvement in resist performance or there is degradation in the formation of consistent resist layers.

In some embodiments, the polymerizable monomer or oligomer includes an acrylic acid, an acrylate, a hydroxystyrene, or an alkylene. In some embodiments, the polymer includes a hydrocarbon structure (such as an alicyclic hydrocarbon structure) that contains one or more groups that will decompose (e.g., acid labile groups) or otherwise react when mixed with acids, bases, or free radicals generated by the PACs (as further described below). In some embodiments, the hydrocarbon structure includes a repeating unit that forms a skeletal backbone of the polymer resin. This repeating unit may include acrylic esters, methacrylic esters, crotonic esters, vinyl esters, maleic diesters, fumaric diesters, itaconic diesters, (meth)acrylonitrile, (meth)acrylamides, styrenes, vinyl ethers, combinations of these, or the like.

Specific structures that are utilized for the repeating unit of the hydrocarbon structure in some embodiments, include one or more of methyl acrylate, ethyl acrylate, n-propyl acrylate, isopropyl acrylate, n-butyl acrylate, isobutyl acrylate, tert-butyl acrylate, n-hexyl acrylate, 2-ethylhexyl acrylate, acetoxyethyl acrylate, phenyl acrylate, 2-hydroxyethyl acrylate, 2-methoxyethyl acrylate, 2-ethoxyethyl acrylate, 2-(2-methoxyethoxy)ethyl acrylate, cyclohexyl acrylate, benzyl acrylate, 2-alkyl-2-adamantyl (meth)acrylate or dialkyl(1-adamantyl)methyl (meth)acrylate, methyl methacrylate, ethyl methacrylate, n-propyl methacrylate, isopropyl methacrylate, n-butyl methacrylate, isobutyl methacrylate, tert-butyl methacrylate, n-hexyl methacrylate, 2-ethylhexyl methacrylate, acetoxyethyl methacrylate, phenyl methacrylate, 2-hydroxyethyl methacrylate, 2-methoxyethyl methacrylate, 2-ethoxyethyl methacrylate, 2-(2-methoxyethoxy)ethyl methacrylate, cyclohexyl methacrylate, benzyl methacrylate, 3-chloro-2-hydroxypropyl methacrylate, 3-acetoxy-2-hydroxypropyl methacrylate, 3-chloroacetoxy-2-hydroxypropyl methacrylate, butyl crotonate, hexyl crotonate, or the like. Examples of the vinyl esters include vinyl acetate, vinyl propionate, vinyl butylate, vinyl methoxyacetate, vinyl benzoate, dimethyl maleate, diethyl maleate, dibutyl maleate, dimethyl fumarate, diethyl fumarate, dibutyl fumarate, dimethyl itaconate, diethyl itaconate, dibutyl itaconate, acrylamide, methyl acrylamide, ethyl acrylamide, propyl acrylamide, n-butyl acrylamide, tert-butyl acrylamide, cyclohexyl acrylamide, 2-methoxyethyl acrylamide, dimethyl acrylamide, diethyl acrylamide, phenyl acrylamide, benzyl acrylamide, methacrylamide, methyl methacrylamide, ethyl methacrylamide, propyl methacrylamide, n-butyl methacrylamide, tert-butyl methacrylamide, cyclohexyl methacrylamide, 2-methoxyethyl methacrylamide, dimethyl methacrylamide, diethyl methacrylamide, phenyl methacrylamide, benzyl methacrylamide, methyl vinyl ether, butyl vinyl ether, hexyl vinyl ether, methoxyethyl vinyl ether, dimethylaminoethyl vinyl ether, or the like. Examples of styrenes include styrene, methyl styrene, dimethyl styrene, trimethyl styrene, ethyl styrene, isopropyl styrene, butyl styrene, methoxy styrene, butoxy styrene, acetoxy styrene, hydroxy styrene, chloro styrene, dichloro styrene, bromo styrene, vinyl methyl benzoate, α-methyl styrene, maleimide, vinylpyridine, vinylpyrrolidone, vinylcarbazole, combinations of these, or the like.

In some embodiments, the polymer is a polyhydroxystyrene, a polymethyl methacrylate, or a polyhydroxystyrene-t-butyl acrylate, e.g.—

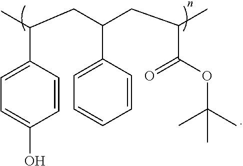

In some embodiments, the repeating unit of the hydrocarbon structure also has either a monocyclic or a polycyclic hydrocarbon structure substituted into it, or the monocyclic or polycyclic hydrocarbon structure is the repeating unit, in order to form an alicyclic hydrocarbon structure. Specific examples of monocyclic structures in some embodiments include bicycloalkane, tricycloalkane, tetracycloalkane, cyclopentane, cyclohexane, or the like. Specific examples of polycyclic structures in some embodiments include adamantane, norbornane, isobornane, tricyclodecane, tetracyclododecane, or the like.

The group which will decompose, otherwise known as a leaving group or, in some embodiments in which the PAC is a photoacid generator, an acid labile group, is attached to the hydrocarbon structure so that, it will react with the acids generated by the PACs during exposure. In some embodiments, the group which will decompose is a carboxylic acid group, a fluorinated alcohol group, a phenolic alcohol group, a sulfonic group, a sulfonamide group, a sulfonylimido group, an (alkylsulfonyl) (alkylcarbonyl)methylene group, an (alkylsulfonyl)(alkyl-carbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl methylene group, a tris(alkylsulfonyl)methylene group, combinations of these, or the like. Specific groups that are used for the fluorinated alcohol group include fluorinated hydroxyalkyl groups, such as a hexafluoroisopropanol group in some embodiments. Specific groups that are used for the carboxylic acid group include acrylic acid groups, methacrylic acid groups, or the like.

In some embodiments, the polymer also includes other groups attached to the hydrocarbon structure that help to improve a variety of properties of the polymerizable resin. For example, inclusion of a lactone group to the hydrocarbon structure assists to reduce the amount of line edge roughness after the photoresist has been developed, thereby helping to reduce the number of defects that occur during development. In some embodiments, the lactone groups include rings having five to seven members, although any suitable lactone structure may alternatively be used for the lactone group.

In some embodiments, the polymer includes groups that can assist in increasing the adhesiveness of the photoresist layer 15 to underlying structures (e.g., target layer 20). Polar groups may be used to help increase the adhesiveness. Suitable polar groups include hydroxyl groups, cyano groups, or the like, although any suitable polar group may, alternatively, be used.

Optionally, the polymer includes one or more alicyclic hydrocarbon structures that do not also contain a group, which will decompose in some embodiments. In some embodiments, the hydrocarbon structure that does not contain a group which will decompose includes structures such as 1-adamantyl(meth)acrylate, tricyclodecanyl (meth)acrylate, cyclohexyl (methacrylate), combinations of these, or the like.

In some embodiments, such as when EUV radiation is used, the photoresist compositions according to some embodiments contain a metal. The metal-containing resists include metallic cores complexed with one or more ligands in a solvent. In some embodiments, the resist includes metal particles. In some embodiments, the metal particles are nanoparticles. As used herein, nanoparticles are particles having an average particle size between about 1 nm and about 20 nm. In some embodiments, the metallic cores, including from 1 to about 18 metal particles, are complexed with one or more organic ligands in a solvent. In some embodiments, the metallic cores include 3, 6, 9, or more metal nanoparticles complexed with one or more organic ligands in a solvent.

In some embodiments, the metal particle is one or more of titanium (Ti), zinc (Zn), zirconium (Zr), nickel (Ni), cobalt (Co), manganese (Mn), copper (Cu), iron (Fe), strontium (Sr), tungsten (W), vanadium (V), chromium (Cr), tin (Sn), hafnium (Hf), indium (In), cadmium (Cd), molybdenum (Mo), tantalum (Ta), niobium (Nb), aluminum (Al), cesium (Cs), barium (Ba), lanthanum (La), cerium (Ce), silver (Ag), antimony (Sb), combinations thereof, or oxides thereof. In some embodiments, the metal particles include one or more selected from the group consisting of Ce, Ba, La, Ce, In, Sn, Ag, Sb, and oxides thereof.

In some embodiments, the metal nanoparticles have an average particle size between about 2 nm and about 5 nm. In some embodiments, the amount of metal nanoparticles in the resist composition ranges from about 0.5 wt. % to about 15 wt. % based on the weight of the nanoparticles and the solvent. In some embodiments, the amount of nanoparticles in the resist composition ranges from about 5 wt. % to about 10 wt. % based on the weight of the nanoparticles and the solvent. In some embodiments, the concentration of the metal particles ranges from 1 wt. % to 7 wt. % based on the weight of the solvent and the metal particles. Below about 0.5 wt. % metal nanoparticles, the resist coating is too thin. Above about 15 wt. % metal nanoparticles, the resist coating is too thick and viscous.

In some embodiments, the metallic core is complexed by a ligand, wherein the ligand includes branched or unbranched, cyclic or non-cyclic, saturated organic groups, including C1-C7 alkyl groups or C1-C7 fluoroalkyl groups. The C1-C7 alkyl groups or C1-C7 fluoroalkyl groups include one or more substituents selected from the group consisting of —CF₃, —SH, —OH, ═O, —S—, —P—, —PO₂, —C(═O)SH, —C(═O)OH, —C(═O)O—, —O—, —N—, —C(═O)NH, —SO₂OH, —SO₂SH, —SOH, and —SO₂—. In some embodiments, the ligand includes one or more substituents selected from the group consisting of —CF₃, —OH, —SH, and —C(═O)OH substituents.

In some embodiments, the ligand is a carboxylic acid or sulfonic acid ligand. For example, in some embodiments, the ligand is a methacrylic acid. In some embodiments, the metal particles are nanoparticles, and the metal nanoparticles are complexed with ligands including aliphatic or aromatic groups. The aliphatic or aromatic groups may be unbranched or branched with cyclic or noncyclic saturated pendant groups containing 1-9 carbons, including alkyl groups, alkenyl groups, and phenyl groups. The branched groups may be further substituted with oxygen or halogen. In some embodiments, each metal particle is complexed by 1 to 25 ligand units. In some embodiments, each metal particle is complexed by 3 to 18 ligand units. In some embodiments, the organometallic

In some embodiments, the resist composition includes about 0.1 wt. % to about 20 wt. % of the ligands based on the total weight of the resist composition. In some embodiments, the resist includes about 1 wt. % to about 10 wt. % of the ligands. In some embodiments, the ligand concentration is about 10 wt. % to about 40 wt. % based on the weight of the metal particles and the weight of the ligands. Below about 10 wt. %, ligand, the organometallic photoresist does not function well. Above about 40 wt. %, ligand, it is difficult to form a consistent photoresist layer. In some embodiments, the ligand(s) is dissolved at about a 5 wt. % to about 10 wt. % weight range in a coating solvent, such as propylene glycol methyl ether acetate (PGMEA) based on the weight of the ligand(s) and the solvent.

In some embodiments, the copolymers and the PACs, along with any desired additives or other agents, are added to the solvent for application. Once added, the mixture is then mixed in order to achieve a homogenous composition throughout the photoresist to ensure that there are no defects caused by uneven mixing or nonhomogeneous composition of the photoresist. Once mixed together, the photoresist may either be stored prior to its usage or used immediately.

The solvent can be any suitable solvent. In some embodiments, the solvent is one or more selected from propylene glycol methyl ether acetate (PGMEA), propylene glycol monomethyl ether (PGME), 1-ethoxy-2-propanol (PGEE), γ-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK).

Some embodiments of the photoresist include one or more photoactive compounds (PACs). The PACs are photoactive components, such as photoacid generators (PAG). The PACs may be positive-acting or negative-acting. In some embodiments in which the PACs are a photoacid generator, the PACs include halogenated triazines, onium salts, diazonium salts, aromatic diazonium salts, phosphonium salts, sulfonium salts, iodonium salts, imide sulfonate, oxime sulfonate, diazodisulfone, disulfone, o-nitrobenzylsulfonate, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and the s-triazine derivatives, combinations of these, or the like.

Specific examples of photoacid generators include α-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-α-(p-toluenesulfonyloxy)-acetate and t-butyl-α-(p-toluenesulfonyloxy)-acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl)sulfonate and bis-(di-t-butylphenyl)iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis-(t-butylphenyl)iodonium triflate; pyrogallol derivatives (e.g., trimesylate of pyrogallol), trifluoromethanesulfonate esters of hydroxyimides, α,α′-bis-sulfonyl-diazomethanes, sulfonate esters of nitro-substituted benzyl alcohols, naphthoquinone-4-diazides, alkyl disulfones, or the like.

As one of ordinary skill in the art will recognize, the chemical compounds listed herein are merely intended as illustrated examples of the PACs and are not intended to limit the embodiments to only those PACs specifically described. Rather, any suitable PAC may be used, and all such PACs are fully intended to be included within the scope of the present embodiments.

In some embodiments, a crosslinker is added to the photoresist. The crosslinker reacts with one group from one of the hydrocarbon structures in the polymer resin and also reacts with a second group from a separate one of the hydrocarbon structures in order to crosslink and bond the two hydrocarbon structures together. This bonding and crosslinking increases the molecular weight of the polymer products of the crosslinking reaction and increases the overall linking density of the photoresist. Such an increase in density and linking density helps to improve the resist pattern.

In some embodiments the crosslinker has the following structure:

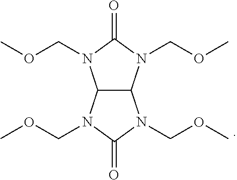

In other embodiments, the crosslinker has the following structure:

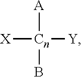

wherein C is carbon, n ranges from 1 to 15; A and B independently include a hydrogen atom, a hydroxyl group, a halide, an aromatic carbon ring, or a straight or cyclic alkyl, alkoxyl/fluoro, alkyl/fluoroalkoxyl chain having a carbon number of between 1 and 12, and each carbon C contains A and B; a first terminal carbon C at a first end of a carbon C chain includes X and a second terminal carbon C at a second end of the carbon chain includes Y, wherein X and Y independently include an amine group, a thiol group, a hydroxyl group, an isopropyl alcohol group, or an isopropyl amine group, except when n=1 then X and Y are bonded to the same carbon C. Specific examples of materials that may be used as the crosslinker include the following:

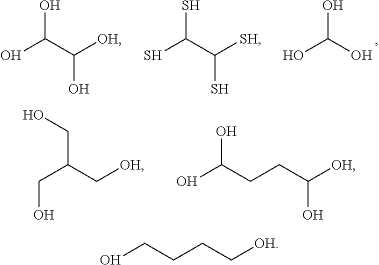

Alternatively, instead of or in addition to the crosslinker being added to the photoresist composition, a coupling reagent is added in some embodiments, in which the coupling reagent is added in addition to the crosslinker. The coupling reagent assists the crosslinking reaction by reacting with the groups on the hydrocarbon structure in the polymer resin before the crosslinker reagent, allowing for a reduction in the reaction energy of the cross-linking reaction and an increase in the rate of reaction. The bonded coupling reagent then reacts with the crosslinker, thereby coupling the crosslinker to the polymer resin.

Alternatively, in some embodiments in which the coupling reagent is added to the photoresist composition without the crosslinker, the coupling reagent is used to couple one group from one of the hydrocarbon structures in the polymer resin to a second group from a separate one of the hydrocarbon structures in order to cross-link and bond the two polymers together. However, in such an embodiment the coupling reagent, unlike the crosslinker, does not remain as part of the polymer, and only assists in bonding one hydrocarbon structure directly to another hydrocarbon structure.

In some embodiments, the coupling reagent has the following structure:

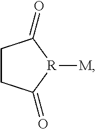

where R is a carbon atom, a nitrogen atom, a sulfur atom, or an oxygen atom; M includes a chlorine atom, a bromine atom, an iodine atom, —NO₂; —SO₃—; —H—; —CN; —NCO, —OCN; —CO₂—; —OH; —OR*, —OC(O)CR*; —SR, —SO₂N(R*)₂; —SO₂R*; SOR; —OC(O)R*; —C(O)OR*; —C(O)R*; —Si(OR*)₃; —Si(R*)₃; epoxy groups, or the like; and R* is a substituted or unsubstituted C1-C12 alkyl, C1-C12 aryl, C1-C12 aralkyl, or the like. Specific examples of materials used as the coupling reagent in some embodiments include the following:

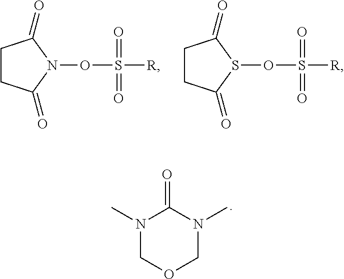

The individual components of the photoresist are placed into a solvent in order to aid in the mixing and dispensing of the photoresist. To aid in the mixing and dispensing of the photoresist, the solvent is chosen at least in part based upon the materials chosen for the polymer resin as well as the PACs. In some embodiments, the solvent is chosen such that the polymer resin and the PACs can be evenly dissolved into the solvent and dispensed upon the layer to be patterned.

In some embodiments, a quencher is added to the photoresist in some embodiments to inhibit diffusion of the generated acids/bases/free radicals within the photoresist. The quencher improves the resist pattern configuration as well as the stability of the photoresist over time.

Another additive added to the photoresist in some embodiments is a stabilizer, which assists in preventing undesired diffusion of the acids generated during exposure of the photoresist.

Another additive added to the photoresist in some embodiments is a dissolution inhibitor to help control dissolution of the photoresist during development.

A coloring agent is another additive added to the photoresist in some embodiments of the photoresist. The coloring agent observers examine the photoresist and find any defects that may need to be remedied prior to further processing.

Surface leveling agents are added to the photoresist in some embodiments to assist a top surface of the photoresist to be level, so that impinging light will not be adversely modified by an unlevel surface.

In some embodiments, the polymer resin and the PACs, along with any desired additives or other agents, are added to the solvent for application. Once added, the mixture is then mixed in order to achieve a homogenous composition throughout the photoresist to ensure that there are no defects caused by uneven mixing or nonhomogenous composition of the photoresist. Once mixed together, the photoresist may either be stored prior to its usage or used immediately.

Once ready, the photoresist is applied onto the underlayer 20, as shown in FIG. 2, to form a photoresist layer 15. In some embodiments, the photoresist is applied using a process such as a spin-on coating process, a dip coating method, an air-knife coating method, a curtain coating method, a wire-bar coating method, a gravure coating method, a lamination method, an extrusion coating method, combinations of these, or the like. In some embodiments, the photoresist layer 15 thickness ranges from about 10 nm to about 300 nm. In some embodiments, the thickness of the photoresist layer 15 is greater than the thickness of the underlayer 20.

The photoresist layer 15 is subsequently patterned in some embodiments by selective exposure to actinic radiation S150, post exposure baking S160, and development S170, as explained herein.

After post exposure baking 5160, the latent pattern in the photoresist layer 15 is developed to form a patterned photoresist layer 55a, 55b. In some embodiments, the photoresist developer 57 includes a solvent, and an acid or a base. In some embodiments, the concentration of the solvent is from about 60 wt. % to about 99 wt. % based on the total weight of the photoresist developer. The acid or base concentration is from about 0.001 wt. % to about 20 wt. % based on the total weight of the photoresist developer. In certain embodiments, the acid or base concentration in the developer is from about 0.01 wt. % to about 15 wt. % based on the total weight of the photoresist developer.

In some embodiments, the developer 57 is applied to the photoresist layer 15 using a spin-on process. In the spin-on process, the developer 57 is applied to the photoresist layer 15 from above the photoresist layer 15 while the photoresist-coated substrate is rotated, as shown in FIG. 4. In some embodiments, the developer 57 is supplied at a rate of between about 5 ml/min and about 800 ml/min, while the photoresist coated substrate 10 is rotated at a speed of between about 100 rpm and about 2000 rpm. In some embodiments, the developer is at a temperature of between about 10° C. and about 80° C. The development operation continues for between about 30 seconds to about 10 minutes in some embodiments.

While the spin-on operation is one suitable method for developing the photoresist layer 15 after exposure, it is intended to be illustrative and is not intended to limit the embodiment. Rather, any suitable development operations, including dip processes, puddle processes, and spray-on methods, may alternatively be used. All such development operations are included within the scope of the embodiments.

During the development process, the developer 57 dissolves the radiation exposed regions 50 of a positive tone resist, dissolves the radiation-unexposed regions 52 of a negative tone resist, exposing the surface of the underlayer 20a, 20b, as shown in FIGS. 5A and 5B. In some embodiments, the underlayer is removed by the developer in the regions where the photoresist is removed by developer. Embodiments of the present disclosure provide patterns having improved definition than provided by conventional photoresist photolithography.

After the developing operation S170, remaining developer is removed from the patterned photoresist covered substrate. The remaining developer is removed using a spin-dry process in some embodiments, although any suitable removal technique may be used. After the photoresist layer 15 is developed, and the remaining developer is removed, additional processing is performed while the patterned photoresist layer 50 is in place. For example, an etching operation, using dry or wet etching, is performed in some embodiments, to transfer the pattern of the photoresist layer 50 through the underlayer 20 to the underlying substrate 10, forming openings 55a′ and 55b′ as shown in FIGS. 6A and 6B. The underlayer 20 and the substrate 10 have a different etch resistance than the photoresist layer 15 in some embodiments. In some embodiments, the etchant is more selective to the underlayer 20 and substrate 10 than the photoresist layer 15. In some embodiments, a different etchant or etching parameters is used to etch the underlayer 20 than to etch the substrate 10. In some embodiments, the exposed underlayer 20 is removed by the same etchant that etches the substrate 10. In other words, the same etching operation is used to etch both the exposed regions of the underlayer 20 and then the exposed regions of the substrate 10.

In some embodiments where the photoresist is a positive tone resist, a pendant PAG group, a pendant TAG group, or a combination thereof is bound to the polymer in the underlayer 20 disposed below the photoresist layer 15. The PAG and TAG groups can be any of the PAG and TAG groups disclosed herein.

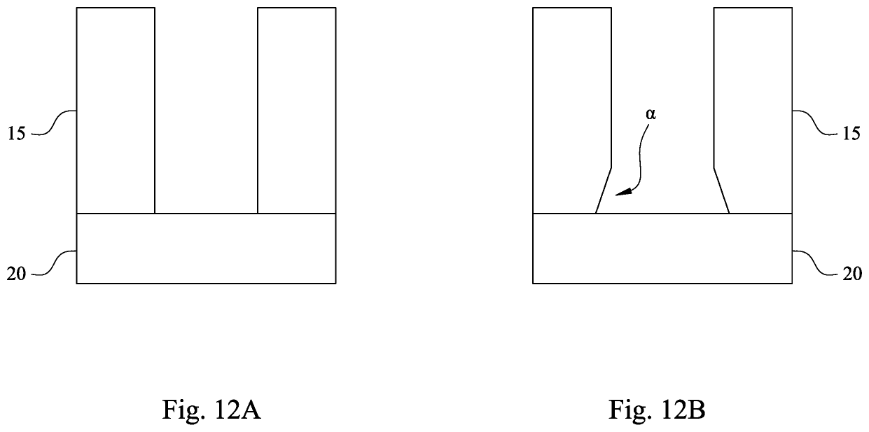

The PAG group or TAG group is used in the resist underlayer (or bottom layer) to increase the acid amount of the bottom portion of the photoresist layer 15 in some embodiments. The acid generated by the PAG group or TAG group supplements the acid generated in the resist layer thereby inhibiting or preventing the formation of bottom scum. When the underlayer polymer does not contain a PAG or TAG group scum may form in the exposed area. Using a lower concentration of the pendant PAG or TAG group in the underlayer composition provides a straight cut resist pattern after development, as shown in FIG. 12A. Using a higher concentration of the pendant PAG or TAG group in the underlayer composition provides a undercut resist pattern after development, as shown in FIG. 12B. In some embodiments, the higher concentration of the PAG or TAG groups is greater than about 30 wt. % based on the total weight of the underlayer composition.

In some embodiments where the photoresist is a negative tone resist, a pendant PBG group, a pendant TBG group, or a combination thereof is bound to the polymer in the underlayer 20 disposed below the photoresist layer 15. The PBG and TBG groups can be any of the PAG and TAG groups disclosed herein.

The pendant PBG group or pendant TBG group bound polymer is used in the resist underlayer 20 (or bottom layer) in some embodiments to decrease the acid amount of the bottom portion of the resist layer. The base generate by the PBG group or TBG group suppresses diffusion of the acid from the radiation exposed areas of the resist layer to the unexposed areas of the resist layer, thereby preventing the formation of bottom scum. When the underlayer polymer does not contain a PBG or TBG group scum may form in the unexposed area. Using a lower concentration of the pendant PBG or TBG group in the underlayer composition provides a straight cut resist pattern after development, as shown in FIG. 12A. Using a higher concentration of the pendant PBG or TBG group in the underlayer composition provides a undercut resist pattern after development, as shown in FIG. 12B. In some embodiments, the higher concentration of the PBG or TBG groups is greater than about 30 wt. % based on the total weight of the underlayer composition. In some embodiments, the angle of the undercut a ranges from about 1° to about 60°.

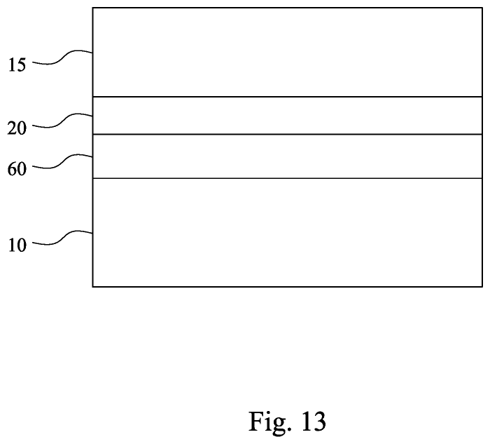

In some embodiments, a target layer 60 to be patterned is disposed over the substrate prior to forming the underlayer 20, as shown in FIG. 13. In some embodiments, the target layer 60 is a semiconductor layer; a conducive layer, such as a metallization layer; or a dielectric layer, such as a passivation layer, disposed over a metallization layer. In embodiments where the target layer 60 is a metallization layer, the target layer 60 is formed of a conductive material using metallization processes, and metal deposition techniques, including chemical vapor deposition, atomic layer deposition, and physical vapor deposition (sputtering). Likewise, if the target layer 60 is a dielectric layer, the target layer 60 is formed by dielectric layer formation techniques, including thermal oxidation, chemical vapor deposition, atomic layer deposition, and physical vapor deposition.

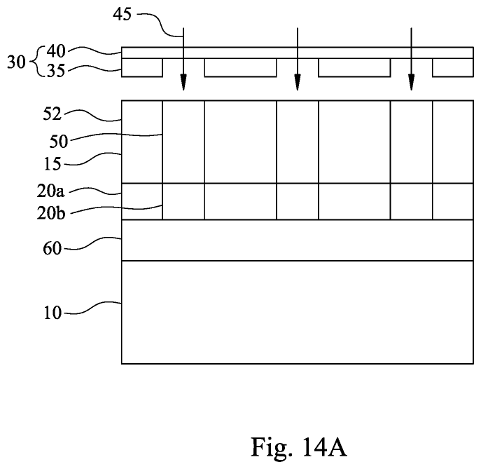

The photoresist layer 15 and resist underlayer 20 are subsequently selectively exposed or patternwise exposed to actinic radiation 45/97 to form exposed regions 50 and 20b and unexposed regions 52 and 20a, in the photoresist layer and underlayer, respectively, as shown in FIGS. 14A and 14B, and described herein in relation to FIGS. 3A and 3B.

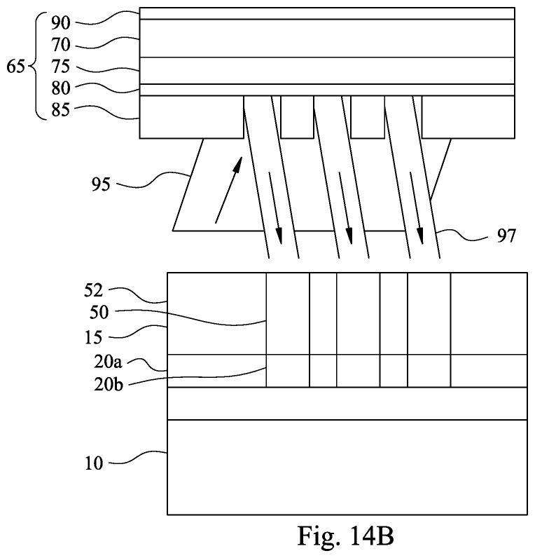

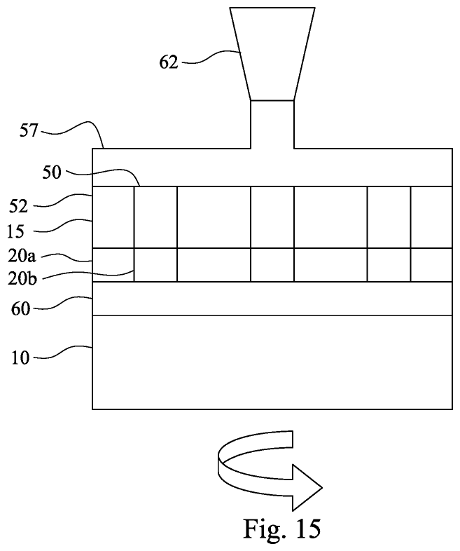

As shown in FIG. 15, the selectively exposed or patternwise exposed photoresist layer 15 is developed by dispensing developer 57 from a dispenser 62 to form a pattern of photoresist openings 55a, 55b, as shown in FIGS. 136 and 16B. FIG. 16A illustrates the development of a positive tone photoresist, and FIG. 16B illustrates the development of a negative tone photoresist. The development operation is similar to that explained with reference to FIGS. 4, 5A, and 5B, herein.

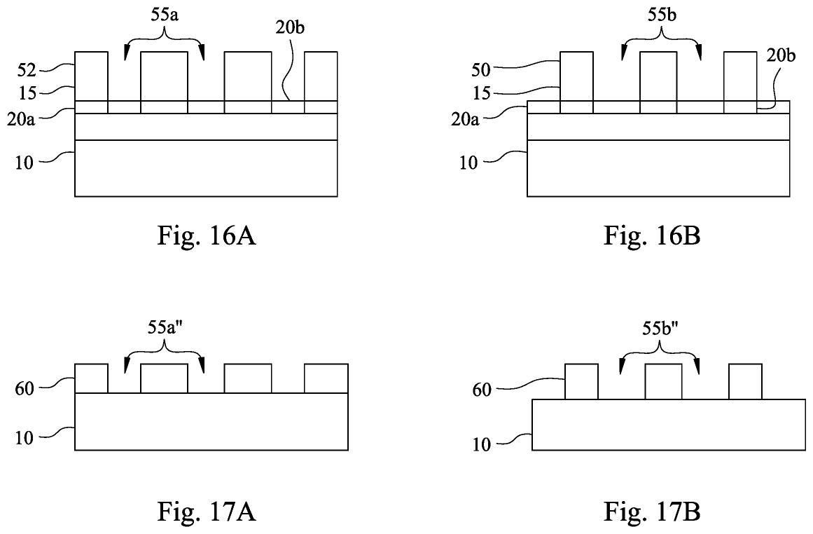

Then, as shown in FIGS. 17A and 17B, the pattern 55a, 55b in the photoresist layer 15 is transferred to the target layer 60 using an etching operation and the photoresist layer and underlayer are removed, as explained with reference to FIGS. 6A and 6B to form pattern 55a″, 55b″ in the target layer 60.

Other embodiments include other operations before, during, or after the operations described above. In some embodiments, the disclosed methods include forming semiconductor devices, including fin field effect transistor (FinFET) structures. In some embodiments, a plurality of active fins are formed on the semiconductor substrate. Such embodiments, further include etching the substrate through the openings of a patterned hard mask to form trenches in the substrate; filling the trenches with a dielectric material; performing a chemical mechanical polishing (CMP) process to form shallow trench isolation (STI) features; and epitaxy growing or recessing the STI features to form fin-like active regions. In some embodiments, one or more gate electrodes are formed on the substrate. Some embodiments include forming gate spacers, doped source/drain regions, contacts for gate/source/drain features, etc. In other embodiments, a target pattern is formed as metal lines in a multilayer interconnection structure. For example, the metal lines may be formed in an inter-layer dielectric (ILD) layer of the substrate, which has been etched to form a plurality of trenches. The trenches may be filled with a conductive material, such as a metal; and the conductive material may be polished using a process such as chemical mechanical planarization (CMP) to expose the patterned ILD layer, thereby forming the metal lines in the ILD layer. The above are non-limiting examples of devices/structures that can be made and/or improved using the method described herein.

In some embodiments, active components such diodes, field-effect transistors (FETs), metal-oxide semiconductor field effect transistors (MOSFET), complementary metal-oxide semiconductor (CMOS) transistors, bipolar transistors, high voltage transistors, high frequency transistors, FinFETs, other three-dimensional (3D) FETs, other memory cells, and combinations thereof are formed, according to embodiments of the disclosure.

Embodiments of the present disclosure allow reduced exposure dose required for the photoresist layer while improving line width roughness, improving line edge roughness, and reducing scum. The novel underlayer compositions and semiconductor device manufacturing methods according to the present disclosure provide higher semiconductor device feature resolution and density at higher wafer exposure throughput with reduced defects in a higher efficiency process than conventional exposure techniques. Embodiments of the disclosure provide improved adhesion of the photoresist pattern to the substrate thereby preventing pattern collapse while preventing pattern scum. Embodiments of the disclosure allow reduced exposure doses and provide increased semiconductor device yield.

An embodiment of the disclosure is a method for manufacturing a semiconductor device, including forming a resist underlayer over a substrate. The resist underlayer includes an underlayer composition, including: a polymer with pendant photoacid generator (PAG) groups, pendant thermal acid generator (TAG) groups, a combination of pendant PAG and pendant TAG groups, pendant photobase generator (PBG) groups, pendant thermal base generator (TBG) groups, or a combination of pendant PBG and pendant TBG groups. A photoresist layer including a photoresist composition is formed over the resist underlayer. The photoresist layer is selectively exposed to actinic radiation. The selectively exposed photoresist layer is developed to form a pattern in the photoresist layer. In an embodiment, the method includes heating the resist underlayer before forming the photoresist layer. In an embodiment, the actinic radiation has a wavelength of less than 250 nm. In an embodiment, the polymer is formed from one or more monomers selected from the group consisting of acrylates, acrylic acids, siloxanes, hydroxystyrenes, methacrylates, vinyl esters, maleic esters, methacrylonitriles, and methacrylamides. In an embodiment, the PAG group, TAG group, PBG group, or TBG group includes an element selected from the group consisting of F, Cl, Br, I, and combinations thereof. In an embodiment, wherein the PAG group, TAG group, PBG group, or TBG group includes a sensitizer core, wherein the sensitizer core includes n aromatic rings, where n≤5, and m proton source functional groups, where m≤2n+3. In an embodiment, wherein the proton source functional groups include —OH or —SH. In an embodiment, wherein a concentration of the PAG group, TAG group, PBG group, or TBG group in the underlayer is less than 50 wt. % based on a total weight of the underlayer composition. In an embodiment, the photoresist composition includes: a polymer, a photoacid generator, and a solvent. In an embodiment, the polymer in the photoresist composition includes an acid labile group (ALG). In an embodiment, the PBG group or TBG group includes an element having a high EUV absorbance. In an embodiment, the photoresist composition further includes a quencher. In an embodiment, the photoresist composition is a positive tone photoresist composition. In an embodiment, the photoresist composition is a negative tone photoresist composition. In an embodiment, the actinic radiation is a KrF laser, an ArF laser, extreme ultraviolet (EUV) radiation, or an electron beam. In an embodiment, the polymer in the underlayer is an organic or inorganic polymer. In an embodiment, the polymer includes the PBG group, and the PBG group is selected from the group consisting of 1,2-dicyclohexyl-4,4,5,5-tetramethylbiguanidium n-butyltriphenylborate, 2-nitrophenyl methyl 4-methacryloyloxy piperidine-1-carboxylate, quaternary ammonium dithiocarbamates, α aminoketones, oxime-urethanes, dibenzophenoneoxime hexamethylene diurethans, ammonium tetraorganylborate salts, and N-(2-nitrobenzyloxycarbonyl)cyclic amines, and combinations thereof. In an embodiment, the polymer includes the PAG group, and the PAG group is one or more selected from the group consisting of N-hydroxynaphthalimide triflate, onium salts, sulfonium salts, triphenylsulfonium triflate, triphenylsulfonium nonaflate, dimethylsulfonium triflate, iodonium salts, diphenyliodonium nonaflate, norbornene dicarboximidyl nonaflate, halogenated triazines, diazonium salts, aromatic diazonium salts, phosphonium salts, imide sulfonates, oxime sulfonates, diazodisulfones, disulfones, o-nitrobenzylsulfonates, sulfonated esters, halogenated sulfonyloxy dicarboximides, diazodisulfones, α-cyanooxyamine-sulfonates, imidesulfonates, ketodiazosulfones, sulfonyldiazoesters, 1,2-di(arylsulfonyl)hydrazines, nitrobenzyl esters, and s-triazines. In an embodiment, the polymer includes the TBG group, and the TBG group is one or more selected from the group consisting of

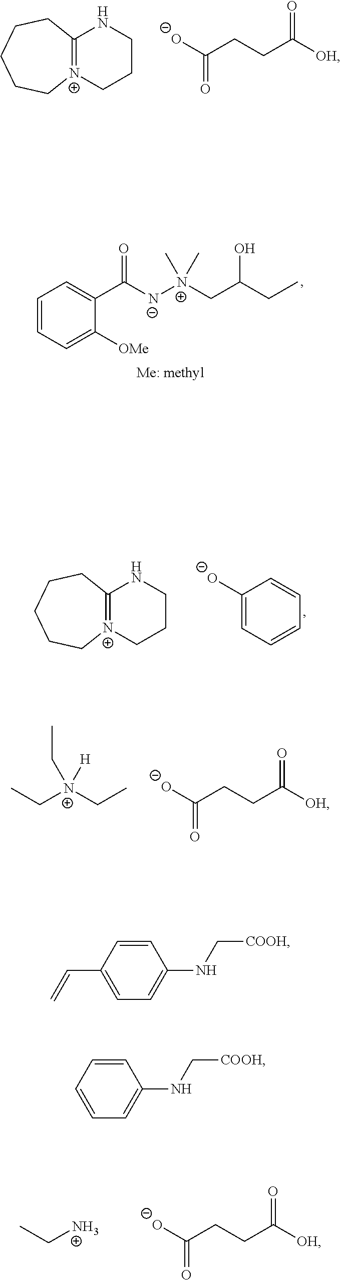

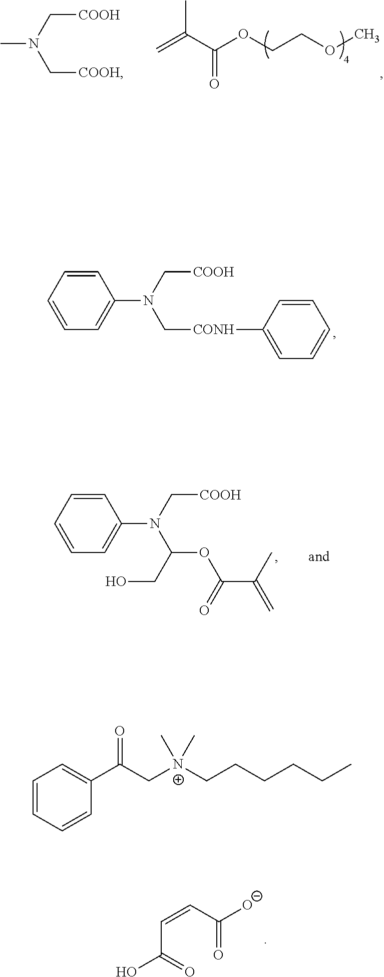

In an embodiment, the polymer includes the TAG group, and the TAG group is one or more selected from the group consisting of

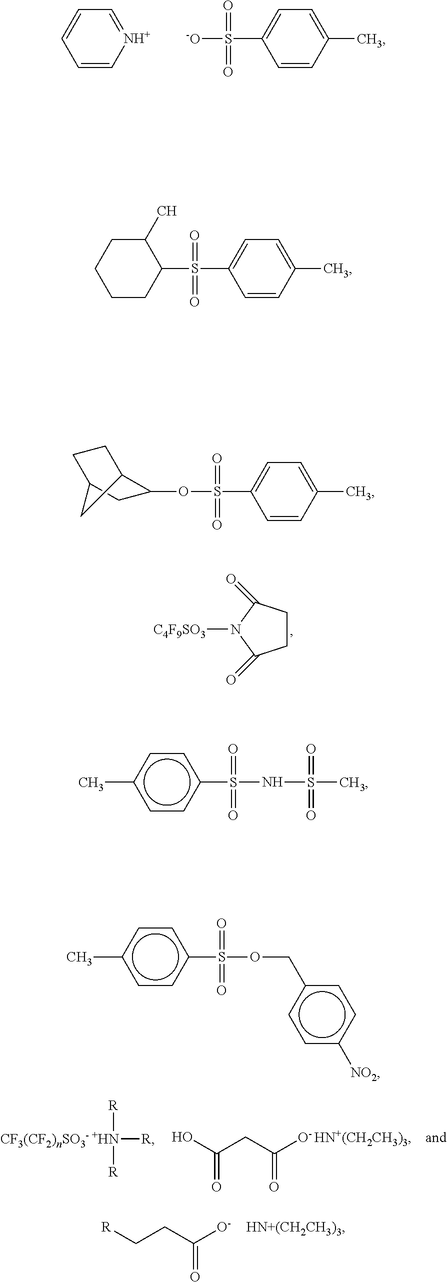

where 0≤n≤10, and R is hydrogen or a substituted or unsubstituted C1-C10 alkyl group. In an embodiment, wherein the PAG group, TAG group, PBG group, and the TBG group includes wherein the PAG group, TAG group, PBG group, and TBG group include a sensitizer core, wherein the sensitizer core includes n aromatic rings, where n≤5, and m proton source functional groups, where m≤2n+3. In an embodiment, the sensitizer core includes a phenyl group, a naphthalenyl group, a phenanthrenthyl group, or an anthracenyl group. In an embodiment, the sensitizer core is one or more selected from the group consisting of 1,3-naphthalenediol, 1-phenanthrenol, and 1,2,3-trihydroxybenzene. In an embodiment, the polymer includes a PAG group or a TAG group, and a pKa of an acid generated by the PAG group or TAG group is less than 1. In an embodiment, the polymer includes a PBG group or a TBG group, and a pKb of a base generated by the PBG or TBG is less than 13.

Another embodiment of the disclosure is a method for manufacturing a semiconductor device, including forming a bottom layer over a substrate, wherein the bottom layer includes a polymer with pendant photoacid generator (PAG) groups, pendant thermal acid generator (TAG) groups, a combination of pendant PAG and pendant TAG groups, pendant photobase generator (PBG) groups, pendant thermal base generator (TBG) groups, or a combination of pendant PBG and pendant TBG groups. A resist layer including a resist composition is formed over the bottom layer and a pattern is formed in the resist layer. In an embodiment, the method includes heating the bottom layer at a temperature ranging from 150° C. to 250° C. before forming the resist layer. In an embodiment, the method includes forming a target layer over the substrate before forming the bottom layer, and extending the pattern in the resist layer into the target layer. In an embodiment, the PAG group, TAG group, PBG group, or TBG group includes an element selected from the group consisting of F, Cl, Br, I, and combinations thereof. In an embodiment, the PAG group, TAG group, PBG group, or TBG group include a sensitizer core, wherein the sensitizer core includes n aromatic rings, where n≤5, and m proton source functional groups, where m≤2n+3.

Another embodiment is a polymer composition, including a polymer having a main chain and pendant photobase generator (PBG) groups, pendant thermal base generator (TBG) groups, or a combination of pendant PBG and pendant TBG groups. In an embodiment, the composition includes a solvent. In an embodiment, the polymer main chain is formed from one or more monomers selected from the group consisting of acrylates, acrylic acids, siloxanes, hydroxystyrenes, methacrylates, vinyl esters, maleic esters, methacrylonitriles, and methacrylamides. In an embodiment, the polymer includes a PBG group or a TBG group, and a pKb of a base generated by the PBG or TBG is less than 13. In an embodiment, the polymer composition includes a quencher. In an embodiment, the PBG group or TBG group includes an element having a high EUV absorbance. In an embodiment, the polymer includes the PBG group selected from the group consisting of 1,2-dicyclohexyl-4,4,5,5-tetramethylbiguanidium n-butyltriphenylborate, 2-nitrophenyl methyl 4-methacryloyloxy piperidine-1-carboxylate, quaternary ammonium dithiocarbamates, α aminoketones, oxime-urethanes, dibenzophenoneoxime hexamethylene diurethans, ammonium tetraorganylborate salts, and N-(2-nitrobenzyloxycarbonyl)cyclic amines, and combinations thereof. In an embodiment, the polymer includes the TBG group, and the TBG group is one or more selected from the group consisting of:

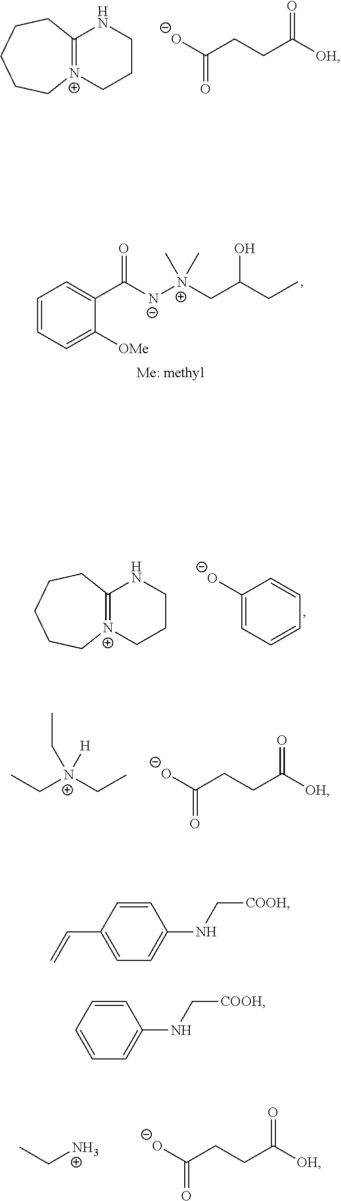

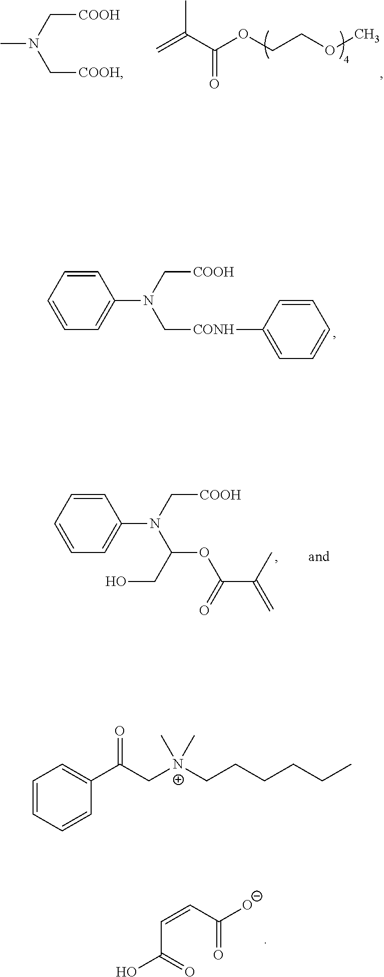

In an embodiment, the PBG group and the TBG group include a sensitizer core, wherein the sensitizer core includes n aromatic rings, where n≤5, and m proton source functional groups, where m≤2n+3. In an embodiment, the sensitizer core is a phenyl group, a naphthalenyl, a phenanthrenthyl group, or an anthracenyl group. In an embodiment, the sensitizer core is one or more selected from the group consisting of 1,3-naphthalenediol, 1-phenanthrenol, and 1,2,3-trihydroxybenzene. In an embodiment, a concentration of the PBG group or TBG group in the polymer composition is less than 50 wt. % based on a total weight of the polymer.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a resist underlayer over a substrate,
wherein the resist underlayer includes an underlayer composition, comprising: a polymer with pendant photoacid generator (PAG) groups, pendant thermal acid generator (TAG) groups, a combination of pendant PAG and pendant TAG groups, pendant photobase generator (PBG) groups, pendant thermal base generator (TBG) groups, or a combination of pendant PBG and pendant TBG groups;
forming a photoresist layer comprising a photoresist composition over the resist underlayer;
selectively exposing the photoresist layer to actinic radiation; and
developing the selectively exposed photoresist layer to form a pattern in the photoresist layer.

2. The method according to claim 1, further comprising heating the resist underlayer before forming the photoresist layer.

3. The method according to claim 1, wherein the actinic radiation has a wavelength of less than 250 nm.

4. The method according to claim 1, wherein the polymer is formed from one or more monomers selected from the group consisting of acrylates, acrylic acids, siloxanes, hydroxystyrenes, methacrylates, vinyl esters, maleic esters, methacrylonitriles, and methacrylamides.

5. The method according to claim 1, wherein the PAG group, TAG group, PBG group, or TBG group includes an element selected from the group consisting of F, Cl, Br, I, and combinations thereof.

6. The method according to claim 1, wherein the PAG group, TAG group, PBG group, or TBG group includes a sensitizer core, wherein the sensitizer core includes n aromatic rings, where n≤5, and m proton source functional groups, where m≤2n+3.

7. The method according to claim 6, wherein the proton source functional groups include —OH or —SH.

8. The method according to claim 1, wherein a concentration of the PAG group, TAG group, PBG group, or TBG group in the underlayer is less than 50 wt. % based on a total weight of the underlayer composition.

9. The method according to claim 1, wherein the photoresist composition comprises:
a polymer;
a photoacid generator; and
a solvent.

10. The method according to claim 9, wherein the polymer in the photoresist composition includes an acid labile group (ALG).

11. A method for manufacturing a semiconductor device, comprising:
forming a bottom layer over a substrate,
wherein the bottom layer includes a polymer with pendant photoacid generator (PAG) groups, pendant thermal acid generator (TAG) groups, a combination of pendant PAG and pendant TAG groups, pendant photobase generator (PBG) groups, pendant thermal base generator (TBG) groups, or a combination of pendant PBG and pendant TBG groups;
forming a resist layer comprising a resist composition over the bottom layer; and
forming a pattern in the resist layer.

12. The method according to claim 11, further comprising heating the bottom layer at a temperature ranging from 150° C. to 250° C. before forming the resist layer.

13. The method according to claim 11, further comprising:
forming a target layer over the substrate before forming the bottom layer; and
extending the pattern in the resist layer into the target layer.

14. The method according to claim 11, wherein the PAG group, TAG group, PBG group, or TBG group includes an element selected from the group consisting of F, Cl, Br, I, and combinations thereof.

15. The method according to claim 11, wherein the PAG group, TAG group, PBG group, or TBG group include a sensitizer core, wherein the sensitizer core includes n aromatic rings, where n≤5, and m proton source functional groups, where m≤2n+3.

16. A polymer composition, comprising:
a polymer having a main chain and pendant photobase generator (PBG) groups, pendant thermal base generator (TBG) groups, or a combination of pendant PBG and pendant TBG groups.

17. The polymer composition of claim 16, wherein the polymer main chain is formed from one or more monomers selected from the group consisting of acrylates, acrylic acids, siloxanes, hydroxystyrenes, methacrylates, vinyl esters, maleic esters, methacrylonitriles, and methacrylamides.

18. The polymer composition of claim 16, wherein the polymer includes a PBG group or a TBG group, and a pKb of a base generated by the PBG or TBG is less than 13.

19. The polymer composition of claim 16, wherein the PBG group and the TBG group include a sensitizer core, wherein the sensitizer core includes n aromatic rings, where n≤5, and m proton source functional groups, where m≤2n+3.

20. The polymer composition of claim 16, further comprising a quencher.
